(19) United States
(12) Patent Application Publication
(10) Pub. No.: US 2010/0117134 A1
(43) Pub. Date: May 13, 2010

(54) SEMICONDUCTOR DEVICE AND METHOD FOR MANUFACTURING SAME

(75) Inventor: Kiyohito NISHIHARA, Kanagawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/562,558

(22) Filed: Sep. 18, 2009

(30) Foreign Application Priority Data
Nov. 10, 2008 (JP) 2008-287697

(51) Int. Cl. H01L 27/105; H01L 21/336

(52) U.S. Cl. 257/314; 438/287; 257/E21.645; 257/E21.423; 257/E27.081

(57) ABSTRACT

A dielectric film is formed on a silicon substrate made of single crystal silicon, an opening is formed in the dielectric film, an amorphous silicon film is formed on the dielectric film, the amorphous silicon film being in contact with the silicon substrate through the opening, solid-phase epitaxial growth of this amorphous silicon film is caused to start at the silicon substrate, and thereafter patterning is performed. Thereby, a seed layer made of the single crystal silicon is formed in part of a region deviated from immediately above the opening. Next, the amorphous silicon film is deposited so as to cover the seed layer, forming a single crystal silicon film by solid-phase epitaxial growth of the amorphous silicon film starting at the seed layer. The silicon pillar is formed by patterning the single crystal silicon film.

### CROSS-REFERENCE TO RELATED APPLICATIONS

This application is based upon and claims the benefit of priority from the prior Japanese Patent Application No. 2008-287697, filed on Nov. 10, 2008; the entire contents of which are incorporated herein by reference.

### BACKGROUND OF THE INVENTION

1. Field of the Invention

This invention relates to a semiconductor device with a semiconductor member provided via a dielectric film on a semiconductor substrate and a method for manufacturing the same.

2. Background Art

Recently, vertical memories have been proposed as NAND flash memories (see, e.g., JP-A-2007-317874 (Kokai)). In a vertical memory, a dielectric film is formed on a substrate. Electrode films and interlayer dielectric films are alternately stacked thereon to form a multilayer body, and trenches are formed in this multilayer body. A charge storage layer is formed on the side surface of the trench, and a semiconductor layer is formed on the side surface and bottom surface of the trench. Then, this semiconductor layer is divided along the extending direction of the trench into a plurality of U-pillars. Thus, a memory cell transistor is formed at the closest point between each pillar and each electrode film with the pillar as an active area and the electrode film as a control gate electrode. In each memory cell transistor, charge is stored in the charge storage layer sandwiched between the pillar and the electrode film, and thereby data is stored. Thus, the density of memory cell transistors can be increased by vertically stacking the memory cell transistors.

However, in such a vertical memory with a semiconductor layer formed on a dielectric film, the semiconductor material used in the active area generally needs to be formed by CVD or the like. Consequently, the active area is made of a polycrystal. This causes the following problems: (1) decreased carrier mobility results in decreasing the current flowing through the pillar; (2) decreased leakage resistance of the pn junction interface in the active area tends to result in faulty NAND operation; (3) active species are trapped and inactivated by the grain boundary, hence decreasing the carrier density in the pillar and decreasing the current flowing through the pillar; and (4) occurrence of energy levels peculiar to the grain boundary makes it difficult to control the threshold of the memory cell. However, conventionally, it has been extremely difficult to form a single crystal pillar on the dielectric film.

### SUMMARY OF THE INVENTION

According to an aspect of the invention, there is provided a semiconductor device including: a semiconductor substrate made of a single crystal semiconductor material; a dielectric film provided on the semiconductor substrate and including an opening; and a semiconductor member provided on the dielectric film, placed in a region deviated from immediately above the opening, made of the single crystal semiconductor material, and separated from the semiconductor substrate.

According to another aspect of the invention, there is provided a semiconductor device including: a semiconductor substrate made of a single crystal semiconductor material; a dielectric film provided on the semiconductor substrate and including an opening extending in one direction; a multilayer body provided on the dielectric film, including a plurality of electrode films and a plurality of interlayer dielectric films alternately stacked, and including a trench extending in the one direction in a region deviated from immediately above the opening; a charge film provided on a side surface of the trench; a U-shaped semiconductor pillar provided on the side surface and a bottom surface of the trench, made of the single crystal semiconductor material, separated from the semiconductor substrate, and extending along the side surface and the bottom surface of the trench; a source line provided on the multilayer body and connected to one end of the semiconductor pillar; and a bit line provided on the multilayer body and connected to the other end of the semiconductor pillar.

According to still another aspect of the invention, there is provided a method for manufacturing a semiconductor device, including: forming a dielectric film on a semiconductor substrate made of a single crystal semiconductor material; forming an opening in the dielectric film; forming a first semiconductor film on the dielectric film, the first semiconductor film being in contact with the semiconductor substrate through the opening and crystallized starting at the semiconductor substrate; forming a seed layer made of the single crystal semiconductor material in part of a region deviated from immediately above the opening by selectively removing the first semiconductor film; forming a second semiconductor film covering the seed layer and crystallized starting at the seed layer; and forming a semiconductor member separated from the semiconductor substrate and made of the single crystal semiconductor material by selectively removing the second semiconductor film.

### BRIEF DESCRIPTION OF THE DRAWINGS

FIG. 1 is a plan view illustrating a semiconductor device according to a first embodiment of the invention;

FIG. 2 is a cross-sectional view taken along line A-A′ shown in FIG. 1;

FIG. 3 is a cross-sectional view illustrating a semiconductor device according to a variation of the first embodiment;

FIG. 4 is a plan view illustrating a semiconductor device according to a second embodiment of the invention;

FIG. 5 is a cross-sectional view taken along line B-B′ shown in FIG. 4;

FIGS. 6A to 6F are process cross-sectional views illustrating a method for manufacturing a semiconductor device according to a third embodiment of the invention;

FIGS. 7A to 10B are process cross-sectional views illustrating a method for manufacturing a semiconductor device according to the third embodiment;

FIGS. 11A and 11B are process plan views illustrating the method for manufacturing a semiconductor device according to the third embodiment;

FIGS. 12A and 12B are process cross-sectional views illustrating a method for manufacturing a semiconductor device according to variations of the third embodiment;

FIGS. 13A to 13E are process cross-sectional views illustrating a method for manufacturing a semiconductor device according to a fourth embodiment;

FIGS. 14A to 14G are process cross-sectional views illustrating a method for manufacturing a semiconductor device according to a fifth embodiment;

FIGS. 15A to 15C are process cross-sectional views illustrating a method for manufacturing a semiconductor device according to a sixth embodiment of the invention; and

FIG. 16 is a cross-sectional view illustrating a method for manufacturing a semiconductor device according to the sixth embodiment.

### DETAILED DESCRIPTION OF THE INVENTION

Embodiments of the invention will now be described with reference to the drawings.

At the outset, a first embodiment of the invention is described.

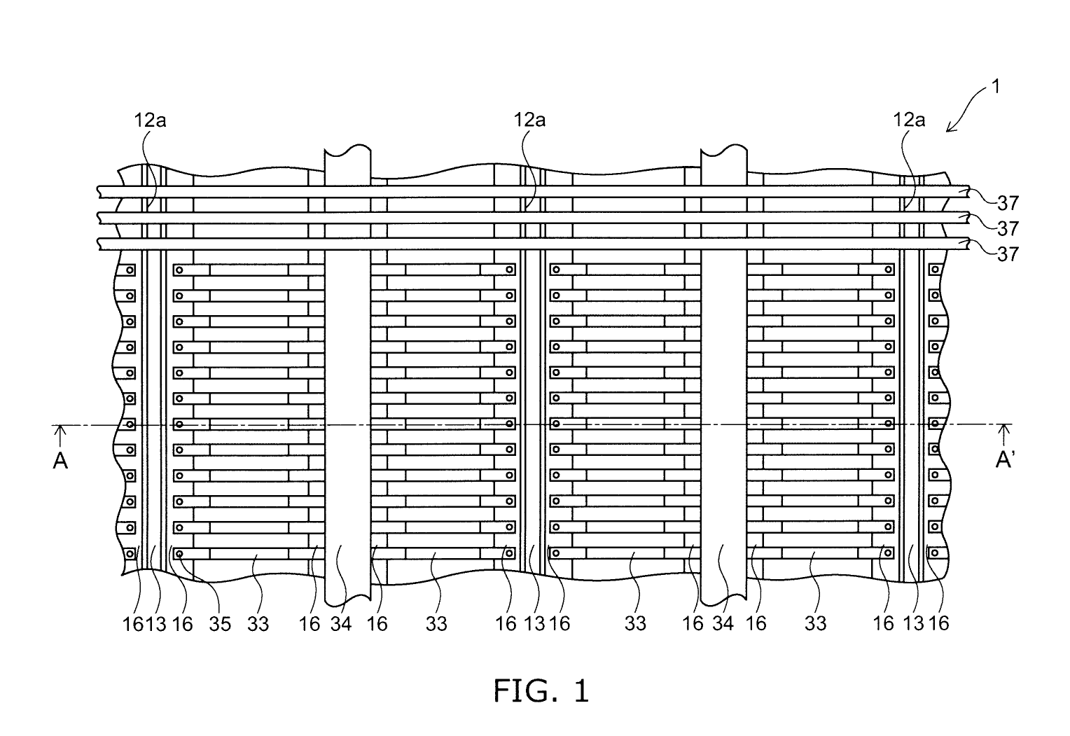

FIG. 1 is a plan view illustrating a semiconductor device according to this embodiment.

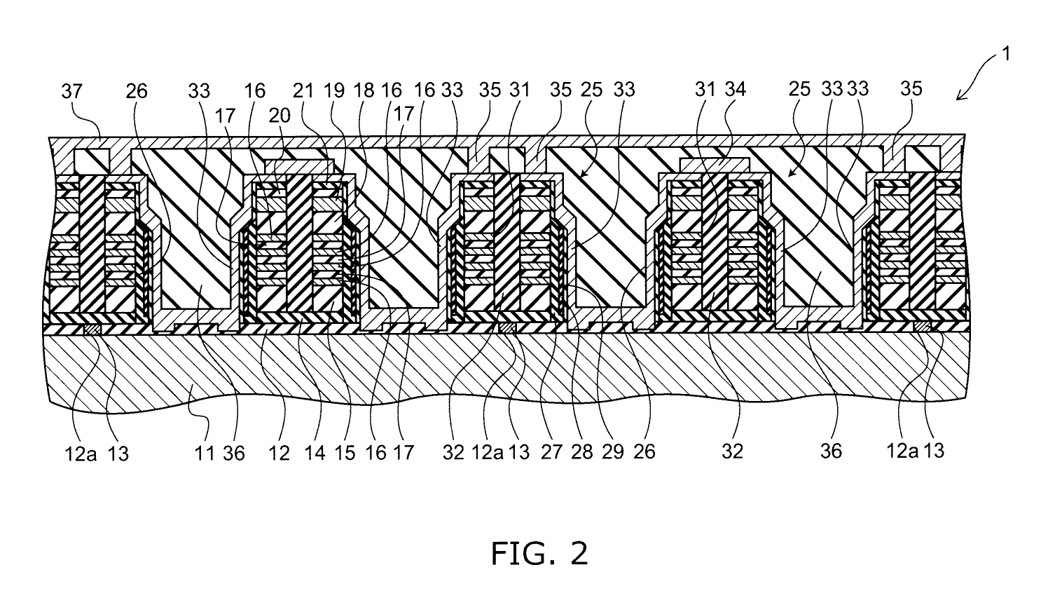

FIG. 2 is a cross-sectional view taken along line A-A′ shown in FIG. 1.

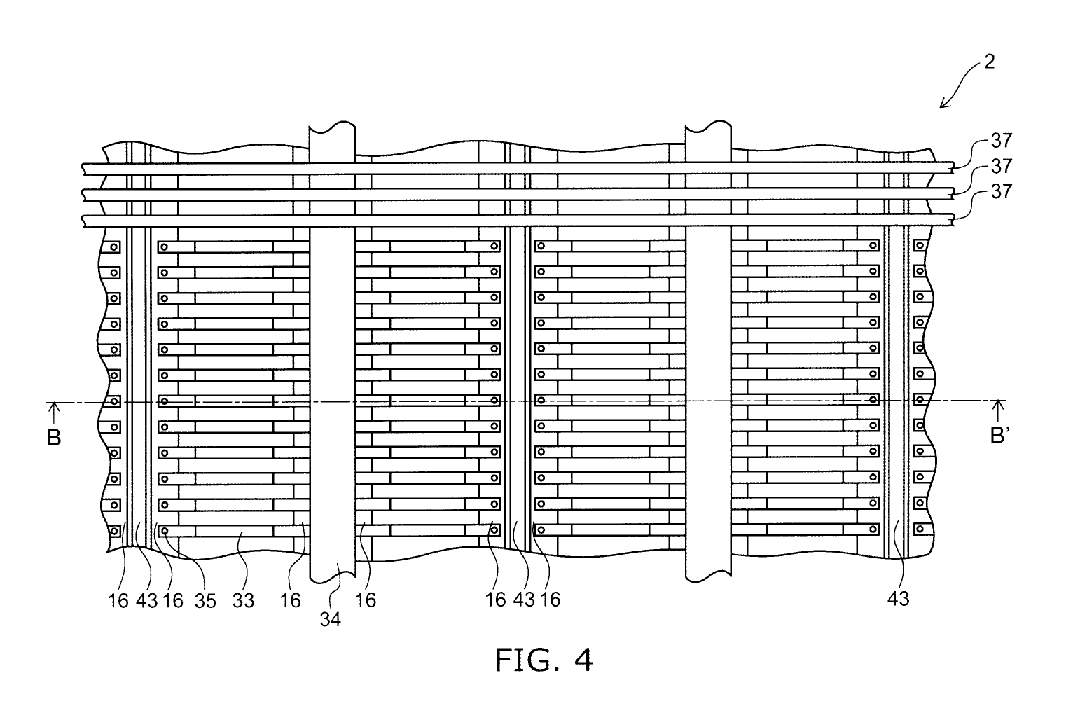

In FIG. 1, for convenience of illustration, illustration of the dielectric portions is omitted, and only the conductive portions are shown. Furthermore, only three of the bit lines are shown in the upper portion of the figure, and illustration of the other bit lines is omitted. This also applies to FIG. 4 described later.

The semiconductor device according to this embodiment is a vertical multilayer NAND flash EEPROM (electrically erasable and programmable read only memory).

As shown in FIGS. 1 and 2, the semiconductor device 1 according to this embodiment includes a silicon substrate 11 made of single crystal silicon. A dielectric film 12 illustratively made of alumina (Al₂O₃) is provided on the silicon substrate 11, and openings 12a are formed in the dielectric film 12. The opening 12a is formed in a line shape extending in one direction. A silicon member 13 epitaxially grown on the silicon substrate 11 is provided in the opening 12a.

A silicon nitride film 14 is provided on the dielectric film 12, and a silicon oxide film 15 is provided thereon. A plurality of electrode films 16 illustratively made of polysilicon and a plurality of interlayer dielectric films 17 illustratively made of silicon oxide are alternately stacked on the silicon oxide film 15, and a silicon oxide film 18, an electrode film 19 made of polysilicon, a silicon oxide film 20, and a silicon nitride film 21 are formed thereon in this order. The silicon nitride film 14, the silicon oxide film 15, the plurality of electrode films 16, the plurality of interlayer dielectric films 17, the silicon oxide film 18, the electrode film 19, the silicon oxide film 20, and the silicon nitride film 21 constitute a multilayer body 25.

A plurality of trenches 26 penetrating through the multilayer body 25 and extending in the same direction as the opening 12a are formed in the multilayer body 25. A block film 27 is formed on the side surface of the lower portion of the trench 26, and a charge film 28 is formed on the block film 27. On the side surface of the trench 26, the block film 27 and the charge film 28 cover the electrode films 16, but do not cover the electrode film 19. A tunnel film 29 is formed entirely on the side surface of the trench 26 so as to cover the block film 27 and the charge film 28. For instance, the block film 27 and the tunnel film 29 are formed from silicon oxide, and the charge film 28 is formed from silicon nitride.

The block film 27 is a film which does not substantially pass a current even if a voltage in the operating voltage range of the semiconductor device 1 is applied. The charge film 28 is a film capable of storing charge, such as a film containing electron trap sites. The tunnel film 29 is a film which is normally insulative, but passes a tunneling current when a prescribed voltage in the operating voltage range of the semiconductor device 1 is applied.

A trench 31 extending in the same direction as the opening 12a and the trench 26 is formed in the region of the multilayer body 25 between the trenches 26. The trench 31 penetrates through the films except the silicon nitride film 14 in the multilayer body 25, and is filled with a dielectric material 32.

Furthermore, on the upper surface of the multilayer body 25 and the side surface and bottom surface of the trench 26, a U-shaped silicon pillar 33 extending in the direction orthogonal to the trench 26 is provided along the upper surface of the multilayer body 25 and the side surface and bottom surface of the trench 26. A plurality of silicon pillars 33 are provided in each trench 26, and arranged along the extending direction of the trench 26. Here, the silicon pillar 33 is not provided inside the trench 31. The silicon pillar 33 is separated and insulated from the silicon substrate 11 by the dielectric film 12. The silicon pillar 33 is formed from single crystal silicon, and has the same crystal orientation as the silicon substrate 11. Furthermore, for instance, the portion of the silicon pillar 33 opposed to the electrode film 19 has p-type conductivity, and the remaining portion has n-type conductivity.

Furthermore, a source line 34 is provided on every other one of the portions of the multilayer body 25 between the trenches 26. The source line 34 is placed on the multilayer body 25, extends in the same direction as the trench 31, straddles the trench 31 in its width direction, and is commonly connected to one end of each of the silicon pillars 33 arranged in two lines on both lateral sides. On the other hand, a bit plug 35 is provided above the portion on the multilayer body 25 between the trenches 26 above which the source line 34 is not provided. The bit plug 35 is not placed immediately above the trench 31. Each bit plug 35 is connected to the other end of one silicon pillar 33.

Furthermore, a dielectric film 36 is provided so as to bury the multilayer body 25, the silicon pillar 33, the source line 34, and the bit plug 35. A plurality of bit lines 37 extending in the direction orthogonal to the trench 26 is provided on the dielectric film 36. The bit line 37 is connected to the other end of the silicon pillar 33 through the bit plug 35. Here, the silicon pillar 33 is placed only immediately below the bit line 37, and not placed immediately below the region between the bit lines 37.

The opening 12a of the dielectric film 12 is placed immediately below every other trench 31. Hence, the silicon pillar 33 placed between the trenches 31 is placed in a region deviated from immediately above the opening 12a. Furthermore, the midpoint of the two adjacent openings 12 is located immediately below the trench 31. Hence, the silicon pillar 33 is placed in a region deviated from immediately above the midpoint of the two adjacent openings 12. Furthermore, of the portions of the multilayer body 25 between the trenches 26, the bit plug 35 is placed immediately above the portion located immediately above the opening 12a, and the source line 34 is placed immediately above the portion not located immediately above the opening 12a.

Next, the operation of the semiconductor device according to this embodiment is described.

In the semiconductor device 1 according to this embodiment, the U-shaped silicon pillar 33 is connected between the bit line 37 and the source line 34. Here, the silicon pillars 33 are separated from each other, and each silicon pillar 33 is separated from the silicon substrate 11 by the dielectric film 12. Hence, each silicon pillar 33 is electrically independent.

A memory transistor is formed at the closest point between each silicon pillar 33 and each electrode film 16 with the silicon pillar 33 constituting an active area and the electrode film 16 constituting a control gate electrode. Hence, in the U-shaped silicon pillar 33, the portion extending in the direction (vertical direction) perpendicular to the upper surface of the silicon substrate 11 constitutes an active area of a plurality of memory cells arranged vertically. Furthermore, a select gate transistor is formed at the closest point between each silicon pillar 33 and the electrode film 19.

Thus, for each silicon pillar 33, a memory string is configured with the select gate transistors provided at both end portions and a plurality of memory transistors connected in series therebetween. In the select gate transistor, the channel region has p-type conductivity, and its overlying region and underlying region have n-type conductivity. Hence, a pn junction interface is formed in the active area of the select gate transistor. Thus, the structure above the dielectric film 12, such as the multilayer body 25, the charge film 28, and the silicon pillar 33, constitutes a memory section.

By controlling the potential of the bit line 37 and the potential of the source line 34, and controlling the potential of the electrode film 19 to control the conduction state of the select gate transistor, the potential of the silicon pillar 33 is controlled, and the potential of the active area of each memory transistor is controlled. On the other hand, by controlling the potential of the electrode film 16, the potential of the control gate electrode of each memory transistor is controlled. Thus, charge is transferred from/to the charge film 28 of each memory transistor, and data is stored.

Here, in the semiconductor device 1, because the silicon pillar 33 is formed from single crystal silicon, the following effects (1)-(4) are achieved.

(1) High carrier mobility in the silicon pillar 33 allows a high current to flow through the silicon pillar 33.

(2) The pn junction interface in the active area of the select gate transistor has high leakage resistance, achieving high reliability in NAND operation.

(3) Active species injected into the silicon pillar 33 are not trapped and inactivated by the grain boundary, hence achieving high carrier density in the silicon pillar and high current flowing through the silicon pillar 33.

(4) No energy level peculiar to the grain boundary occurs in the silicon pillar 33, which facilitates controlling the threshold of the memory transistor.

Thus, according to this embodiment, the silicon pillar 33 formed on the dielectric film 12 is formed from single crystal silicon, and thereby a semiconductor device 1 with good characteristics can be achieved. The method for manufacturing the semiconductor device 1 according to this embodiment is described in detail in the third and fourth embodiment described later.

Next, a variation of the first embodiment is described.

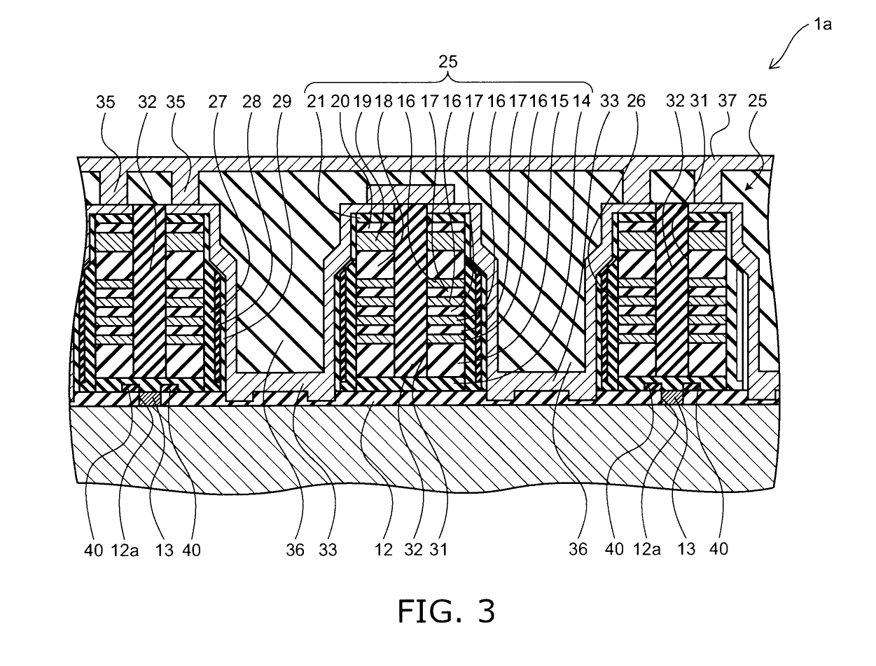

FIG. 3 is a cross-sectional view illustrating a semiconductor device according to this variation.

As shown in FIG. 3, the semiconductor device 1a according to this variation is different from the semiconductor device 1 (see FIGS. 1 and 2) according to the above first embodiment in that a dielectric film 40 is provided on the dielectric film 12. The dielectric film 40 is illustratively made of silicon nitride and locally formed in a region on the dielectric film 12, such as at the edge of the opening 12a, deviated from both the region immediately above the opening 12a and the region where the silicon pillar 33 is placed. As described later in detail in the fifth embodiment, in the process of manufacturing the semiconductor device 1a, the dielectric film 40 functions as a CMP (chemical mechanical polishing) stopper film. The operation and effect of this variation are the same as those of the above first embodiment.

Next, a second embodiment of the invention is described.

FIG. 4 is a plan view illustrating a semiconductor device according to this embodiment.

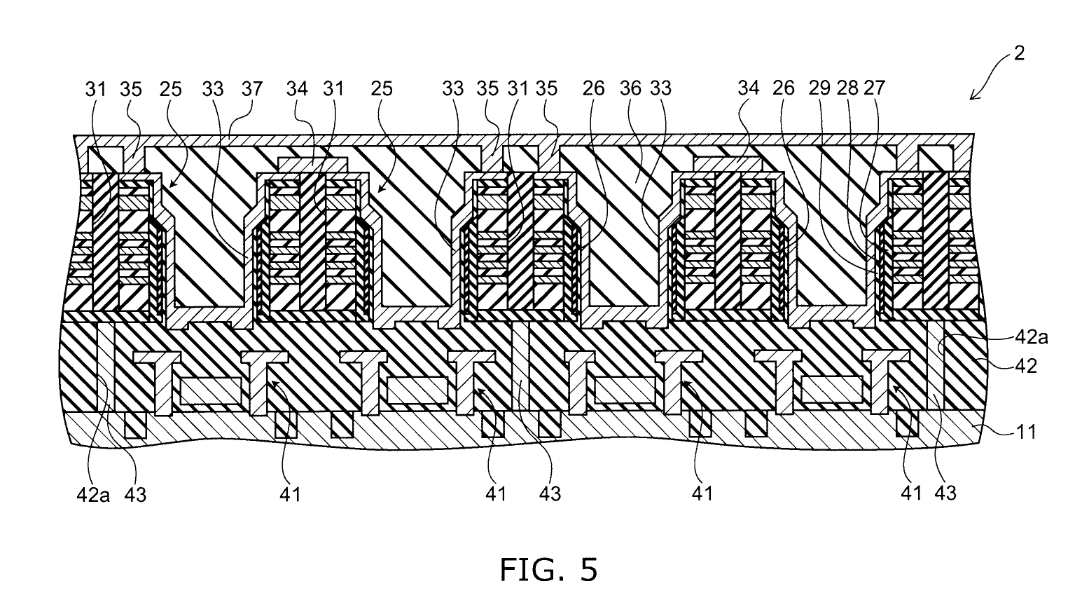

FIG. 5 is a cross-sectional view taken along line B-B′ shown in FIG. 4.

The semiconductor device according to this embodiment is also a vertical multilayer NAND flash EEPROM, like the above first embodiment.

As shown in FIGS. 4 and 5, the semiconductor device 2 according to this embodiment is different from the semiconductor device 1 (see FIGS. 1 and 2) according to the above first embodiment in that an interlayer dielectric film 42 is provided instead of the dielectric film 12, and peripheral elements 41 are formed in the upper portion of the silicon substrate 11 and inside the interlayer dielectric film 42. The peripheral element 41 is illustratively a high-voltage transistor having a breakdown voltage of approximately 25 V (volts). Through trenches 42a are formed as openings in the interlayer dielectric film 42. The through trench 42a extends in the extending direction of the source line 34, having a lower end reaching the silicon substrate 11 and an upper end reaching the multilayer body 25. A silicon member 43 epitaxially grown on the silicon substrate 11 is buried inside the through trench 42a.

The configuration of the portion above the interlayer dielectric film 42 in the semiconductor device 2 is the same as the configuration of the portion above the dielectric film 12 in the semiconductor device 1 (see FIGS. 1 and 2) according to the above first embodiment. That is, a multilayer body 25 is provided on the interlayer dielectric film 42. Trenches 26 and trenches 31 extending in the extending direction of the through trench 42a are alternately formed in the multilayer body 25. A block film 27, a charge film 28, and a tunnel film 29 are laminated in this order on the side surface of the trench 26. A plurality of U-shaped silicon pillars 33 made of single crystal silicon are provided thereon. The silicon pillars 33 are arranged along the extending direction of the trench 26.

Thus, in the semiconductor device 2, the upper portion of the silicon substrate 11 and the interlayer dielectric film 42 constitute a peripheral circuit section, and the configuration provided above the peripheral circuit section, such as the multilayer body 25, the charge film 28, and the silicon pillar 33, constitutes a memory section. Hence, in the semiconductor device 2, the memory section is placed on the peripheral circuit section.

The through trench 42a of the interlayer dielectric film 42 is placed immediately below every other trench 31. Thus, the silicon pillar 33 placed between the trenches 31 is placed in a region deviated from immediately above the through trench 42a and deviated from the midpoint of the two adjacent through trenches 42a.

Next, the effect of this embodiment is described.

Also in this embodiment, like the above first embodiment, the silicon pillar 33 is formed from single crystal silicon, and thereby the characteristics of the semiconductor device can be improved. Furthermore, according to this embodiment, the area of the semiconductor device 2 can be reduced by placing the peripheral circuit section immediately below the memory section. Thus, in the semiconductor device 2 viewed as a whole, the density of memory cell transistors can be further increased. The operation and effect of this embodiment other than the foregoing are the same as those of the above first embodiment. The method for manufacturing the semiconductor device 2 according to this embodiment is described in detail in the sixth embodiment described later.

Next, a third embodiment of the invention is described.

This embodiment is a method for manufacturing the semiconductor device according to the above first embodiment.

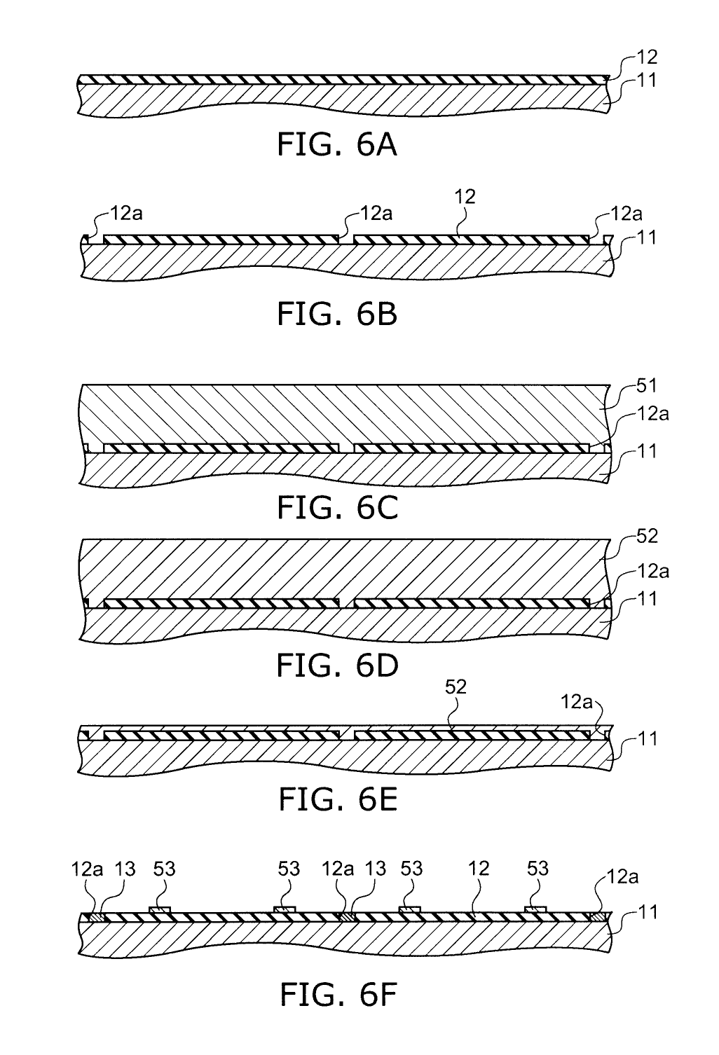

FIGS. 6A to 6F, 7A to 7C, 8A to 8C, 9A to 9C, 10A, and 10B are process cross-sectional views illustrating a method for manufacturing a semiconductor device according to this embodiment.

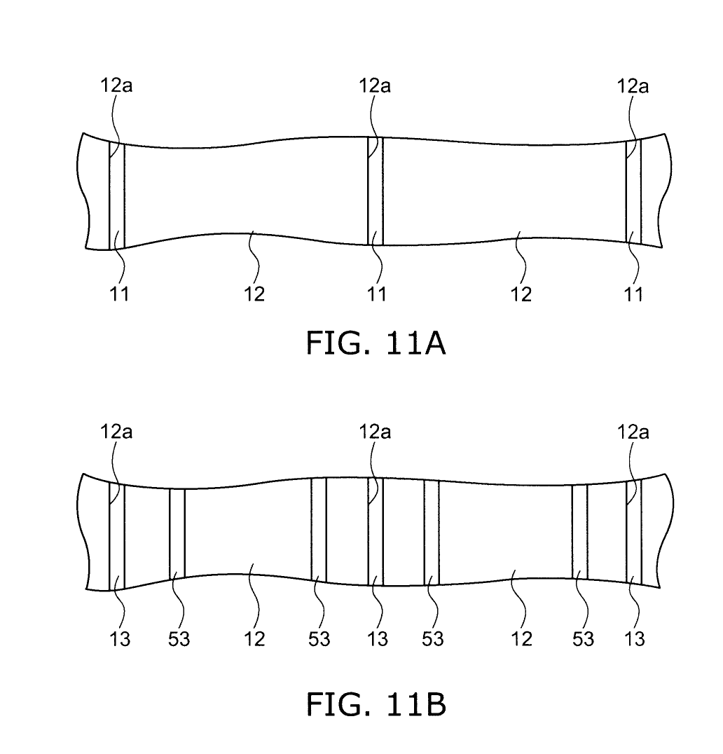

FIGS. 11A and 11B are process plan views illustrating the method for manufacturing a semiconductor device according to this embodiment.

Here, FIG. 11A shows the same step as FIG. 6B, and FIG. 11B shows the same step as FIG. 6F.

As shown in FIG. 6A, a silicon substrate 11 made of single crystal silicon is prepared. Then, a dielectric film 12 is formed on the silicon substrate 11. The dielectric film 12 is illustratively formed from alumina.

As shown in FIGS. 6B and 11A, a resist film (not shown) is formed on the dielectric film 12 and patterned into a mask material. This mask material is used as a mask to perform dry etching, such as RIE (reactive ion etching), or wet etching to form openings 12a in the dielectric film 12. The openings 12a are formed in a striped configuration in a region deviated from a predetermined region of a silicon pillar 33 (see FIG. 2) formed in a later process, and also deviated from the region equidistant from a predetermined regions of the silicon pillar 33, so as to extend in the extending direction of the source line 34 (see FIG. 1) formed in a later process. The upper surface of the silicon substrate 11 is exposed inside the opening 12a.

As shown in FIG. 6C, an amorphous silicon film 51 is deposited entirely on the dielectric film 12. At this time, the amorphous silicon film 51 is buried also inside the opening 12a and brought into contact with the silicon substrate 11 in the opening 12a.

As shown in FIG. 6D, heat treatment is performed to cause solid-phase epitaxial growth of the amorphous silicon film 51 starting at the portion in contact with the silicon substrate 11 through the opening 12a. Thus, the amorphous silicon film 51 is monocrystallized into an epitaxial silicon film 52. The epitaxial silicon film 52 has the same crystal orientation as the silicon substrate 11. Here, in the portion of the epitaxial silicon film 52 having an equal distance from the adjacent openings 12a, crystal growth surfaces meet each other and form a boundary surface containing crystal defects. The epitaxial silicon film 52 is a first semiconductor film provided on the dielectric film 12, being in contact with the silicon substrate 11 through the opening 12a, and crystallized starting at the silicon substrate 11.

As shown in FIG. 6E, the thickness of the epitaxial silicon film 52 is reduced to a prescribed thickness. This thickness reduction is performed illustratively by RIE or CMP.

As shown in FIGS. 6F and 11B, a resist film (not shown) is formed on the epitaxial silicon film 52 and patterned into a mask material. Here, the mask material is formed in a striped configuration extending in the same direction as the opening 12a, in a region deviated from immediately above the opening 12a, and also deviated from immediately above the midpoint of the adjacent openings 12a. This mask material is used as a mask to perform RIE or other etching to selectively remove the epitaxial silicon film 52. Thus, the epitaxial silicon film 52 locally remains and constitutes a seed layer 53. On the other hand, the epitaxial silicon film 52 remains also in the opening 12a and constitutes a silicon member 13 epitaxially grown on the silicon substrate 11.

The seed layer 53 remains immediately below the mask material, and hence is formed in a striped configuration extending in the same direction as the opening 12a, in a region deviated from immediately above the opening 12a, and also deviated from immediately above the midpoint of the adjacent openings 12a. For instance, in this embodiment, the seed layer 53 is formed immediately above the midpoint between the opening 12a and the midpoint between the adjacent openings 12a. That is, denoting by L the distance from one opening 12a to its adjacent opening 12a, the seed layer 53 is formed at a distance of L/4 and 3L/4 from the one opening 12a.

Because the seed layer 53 is formed in a region deviated from immediately above the opening 12a, it is separated from the silicon substrate 11. Furthermore, because the seed layer 53 locally remains as the result of etching of the epitaxial silicon film 52, it is made of single crystal silicon and has the same crystal orientation as the silicon substrate 11. Furthermore, because the seed layer 53 is formed in a region deviated from the midpoint between the adjacent openings 12a, it includes no boundary surface between crystal growth surfaces meeting each other.

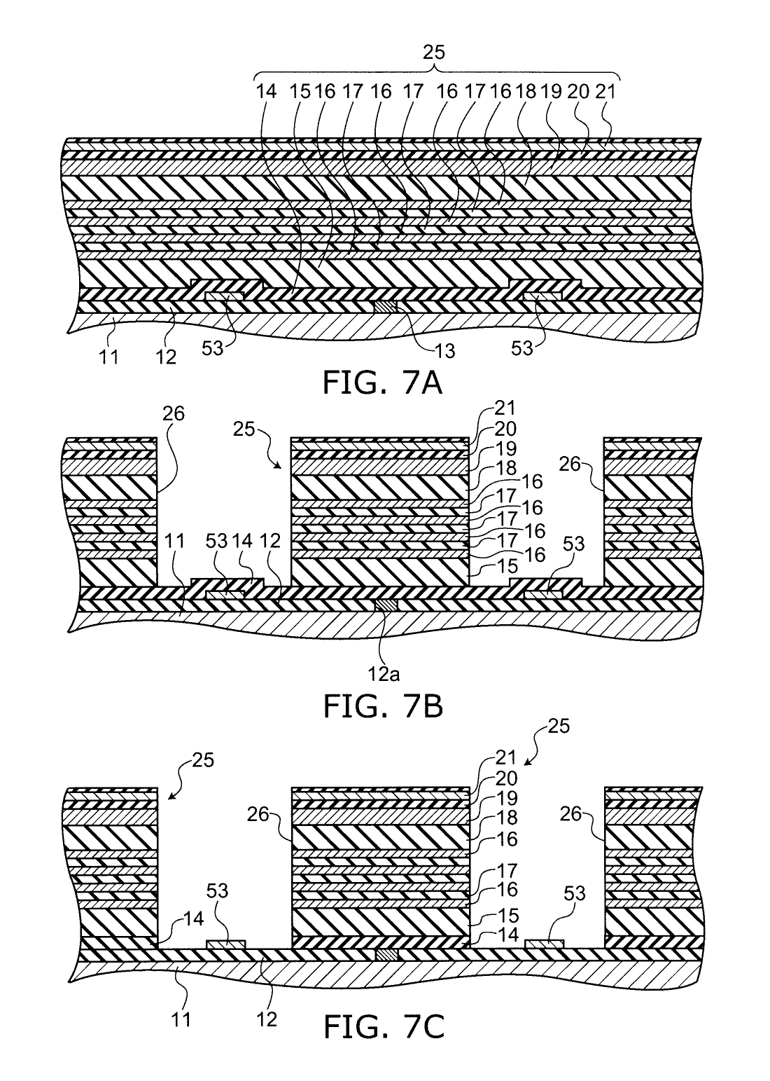

As shown in FIG. 7A, a silicon nitride film 14 is formed on the dielectric film 12 so as to cover the seed layer 53, and a silicon oxide film 15 is formed thereon. Next, a plurality of electrode films 16 illustratively made of polysilicon and a plurality of interlayer dielectric films 17 illustratively made of silicon oxide are alternately stacked on the silicon oxide film 15. Next, a silicon oxide film 18, an electrode film 19 made of polysilicon, a silicon oxide film 20, and a silicon nitride film 21 are formed in this order. Each film is formed illustratively by the CVD (chemical vapor deposition) method. Thus, a multilayer body 25 composed of the silicon nitride film 14, the silicon oxide film 15, the plurality of electrode films 16, the plurality of interlayer dielectric films 17, the silicon oxide film 18, the electrode film 19, the silicon oxide film 20, and the silicon nitride film 21 is formed on the dielectric film 12.

As shown in FIG. 7B, the silicon nitride film 21, the silicon oxide film 20, the electrode film 19, the silicon oxide film 18, the plurality of interlayer dielectric films 17, the plurality of electrode films 16, and the silicon oxide film 15 are selectively removed from regions including the regions immediately above the seed layers 53. Thus, trenches 26 are formed in the multilayer body 25 by etching. The trench 26 extends in the same direction as the opening 12a and the seed layer 53. At this point, the silicon nitride film 14 is exposed to the bottom of the trench 26.

As shown in FIG. 7C, the silicon nitride film 14 is removed from the bottom of the trench 26 by etching further performed. Thus, the dielectric film 12 and the seed layer 53 are exposed to the bottom of the trench 26.

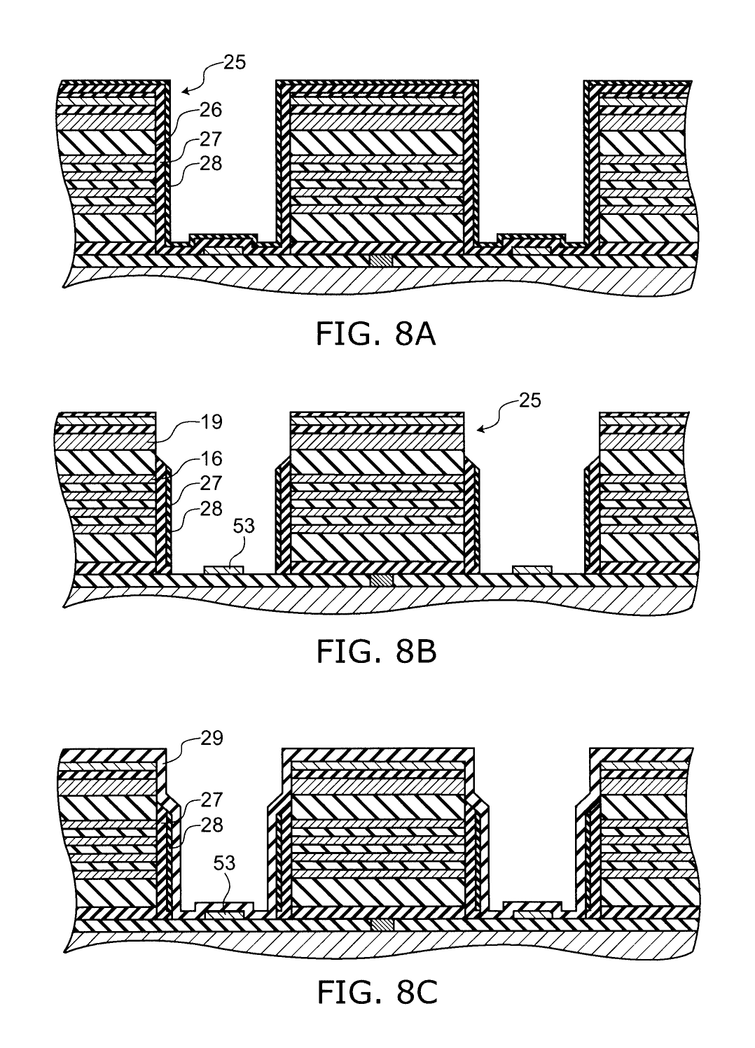

As shown in FIG. 8A, by the CVD method, for instance, a block film 27 illustratively made of silicon oxide is formed on the entire surface, and a charge film 28 illustratively made of silicon nitride is formed on the entire surface. The block film 27 and the charge film 28 are formed on the side surface and bottom surface of the trench 26 as well as on the upper surface of the multilayer body 25.

As shown in FIG. 8B, the charge film 28 and the block film 27 deposited on the upper surface of the multilayer body 25, on the bottom surface of the trench 26, and on the side surface of the upper portion of the trench 26 are removed by anisotropic etching, such as RIE. Thus, on the side surface of the multilayer body 25, the block film 27 and the charge film 28 remain on the region corresponding to the electrode films 16, and do not remain on the region corresponding to the electrode film 19, where the electrode film 19 is exposed.

As shown in FIG. 8C, by the CVD method, for instance, a tunnel film 29 illustratively made of silicon oxide is formed on the entire surface. The tunnel film 29 is formed on the side surface and bottom surface of the trench 26 as well as on the upper surface of the multilayer body 25. Thus, the block film 27, the charge film 28, and the seed layer 53 are covered with the tunnel film 29.

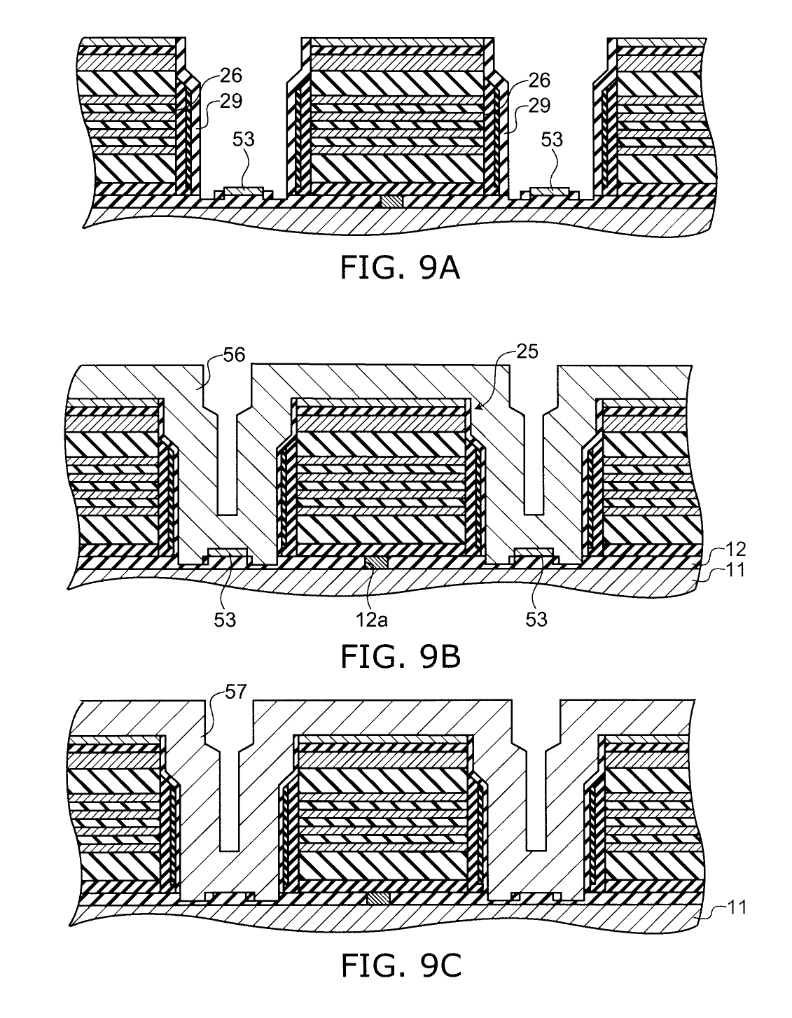

As shown in FIG. 9A, the tunnel film 29 is removed from above the upper surface of the multilayer body 25 and the bottom surface of the trench 26 by anisotropic etching, such as RIE. Thus, the seed layer 53 is exposed to the bottom of the trench 26.

As shown in FIG. 9B, by the CVD method, for instance, an amorphous silicon film 56 is deposited on the entire surface. This amorphous silicon film 56 is formed also inside the trench 26, covers the seed layer 53 at the bottom of the trench 26, and is in contact with the seed layer 53. Here, the silicon substrate 11 is covered with the dielectric film 12, and the opening 12a of the dielectric film 12 is also covered with the multilayer body 25. Hence, the amorphous silicon film 56 is not in contact with the silicon substrate 11.

As shown in FIG. 9C, heat treatment is performed to cause solid-phase epitaxial growth of the amorphous silicon film 56 starting at the seed layer 53. Thus, the amorphous silicon film 56 is turned into an epitaxial silicon film 57. Here, the epitaxial silicon film 57 has the same crystal orientation as the seed layer 53, and hence has the same crystal orientation as the silicon substrate 11. That is, the epitaxial silicon film 57 is a second semiconductor film covering the seed layer 53 and crystallized starting at the seed layer 53.

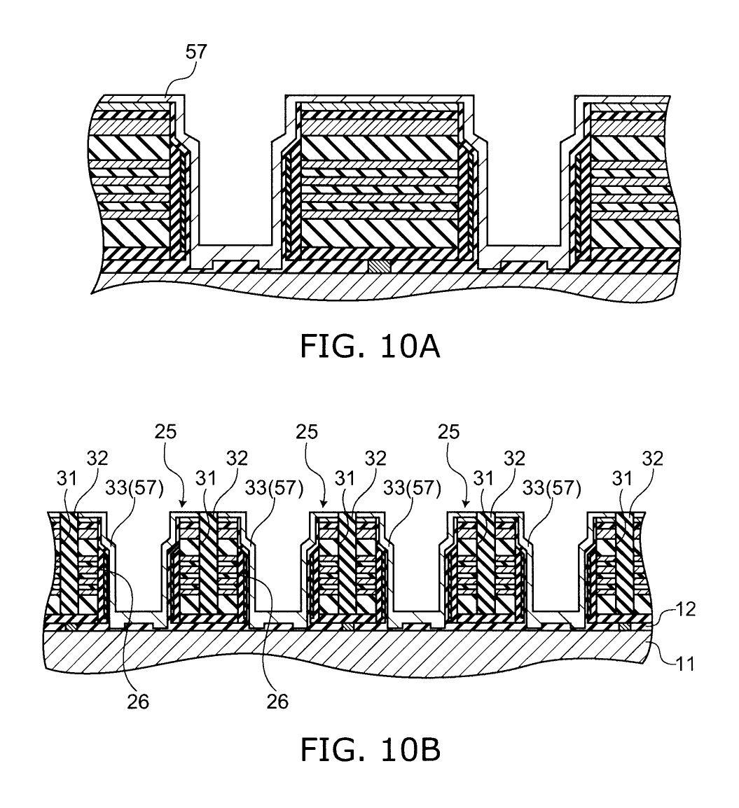

As shown in FIG. 10A, by oxidation or CDE (chemical dry etching), the epitaxial silicon film 57 is isotropically removed to reduce its thickness.

As shown in FIG. 10B, the epitaxial silicon film 57 is selectively removed so that the epitaxial silicon film 57 is divided along the extending direction of the trench 26 and removed from the center region on the upper surface of the multilayer body 25. Thus, a plurality of U-shaped silicon pillars 33 are formed, which are arranged along the extending direction of the trench 26 and extend in the direction orthogonal to the extending direction of the trench 26 along the side surface and bottom surface of the trench 26. Because the silicon pillar 33 is formed by division of the epitaxial silicon film 57, it is made of single crystal silicon and, for instance, has the same crystal orientation as the silicon substrate 11. Furthermore, the silicon pillar 33 is separated from the silicon substrate 11 by the dielectric film 12.

Next, in a portion of the multilayer body 25 between the trenches 26, the silicon nitride film 21, the silicon oxide film 20, the electrode film 19, the silicon oxide film 18, the plurality of interlayer dielectric films 17, the plurality of electrode films 16, and the silicon oxide film 15 are etched away. Thus, a trench 31 extending in the same direction as the trench 26 is formed in the portion of the multilayer body 25 between the trenches 26. The silicon nitride film 14 is exposed to the bottom of the trench 31. Then, a dielectric material 32 is buried in the trench 31.

As shown in FIGS. 1 and 2, a source line 34 illustratively made of a metal is formed on the upper surface of every other one of the portions of the multilayer body 25 between the trenches 26. The source line 34 is formed in a striped configuration so that it straddles the trench 31 in its width direction and that its longitudinal direction is in the same direction as the trench 26. Thus, on both lateral sides of the source line 34, the source line 34 is commonly connected to the end portion of the silicon pillars 33 arranged in two lines in the extending direction of the source line 34.

Next, a dielectric film 36 is formed so as to cover the multilayer body 25 and the source line 34. At this time, the dielectric film 36 is buried also inside the trench 26. Next, a bit plug 35 illustratively made of a metal is buried in the dielectric film 36. The bit plug 35 is formed above the portion of the multilayer body 25 between the trenches 26 on which the source line 34 is not formed. Thus, the bit plug 35 is connected to the end portion of the silicon pillar 33 which is not connected to the source line 34. Next, a bit line 37 illustratively made of a metal is formed on the dielectric film 36 so as to extend in the direction orthogonal to the extending direction of the source line 34. The bit line 37 is formed on a portion including the region immediately above the bit plug 35 so as to be connected to the bit plug 35. Thus, one end portion of each silicon pillar 33 is connected to the source line 34, and the other end portion is connected to the bit line 37 through the bit plug 35. Thus, the semiconductor device 1 according to the above first embodiment is manufactured.

Next, the operation and effect of this embodiment are described.

In this embodiment, in the step shown in FIG. 6B, openings 12a are formed in the dielectric film 12. In the step shown in FIG. 6C, an amorphous silicon film 51 is brought into contact with the silicon substrate 11 through the opening 12a. In the step shown in FIG. 6D, the amorphous silicon film 51 is subjected to solid-phase epitaxial growth starting at the silicon substrate 11 to form an epitaxial silicon film 52. In the step shown in FIGS. 6E and 6F, the epitaxial silicon film 52 is selectively removed to form a seed layer 53 made of single crystal silicon. Then, in the step shown in FIG. 9B, an amorphous silicon film 56 is deposited in contact with the seed layer 53. In the step shown in FIG. 9C, the amorphous silicon film 56 is subjected to solid-phase epitaxial growth starting at the seed layer 53 to form an epitaxial silicon film 57. In the step shown in FIGS. 10A and 10B, the epitaxial silicon film 57 is processed into silicon pillars 33 made of single crystal silicon. Here, the seed layer 53 and the silicon pillar 33 are formed in a region deviated from immediately above the opening 12a, and hence are separated from the silicon substrate 11.

Thus, according to this embodiment, the silicon pillar 33 is formed by epitaxial growth indirectly from the silicon substrate 11 through the seed layer 53. Hence, the silicon pillar 33 can be formed from single crystal silicon while being insulated from the silicon substrate 11 by the dielectric film 12.

Furthermore, the seed layer 53 is formed in a region deviated from the midpoint between the adjacent openings 12a. This can reliably prevent the seed layer 53 from including a boundary surface containing crystal defects, which is formed by crystal growth surfaces meeting each other. Thus, the silicon pillar 33 can be reliably formed from single crystal.

In addition, this embodiment allows the following variations.

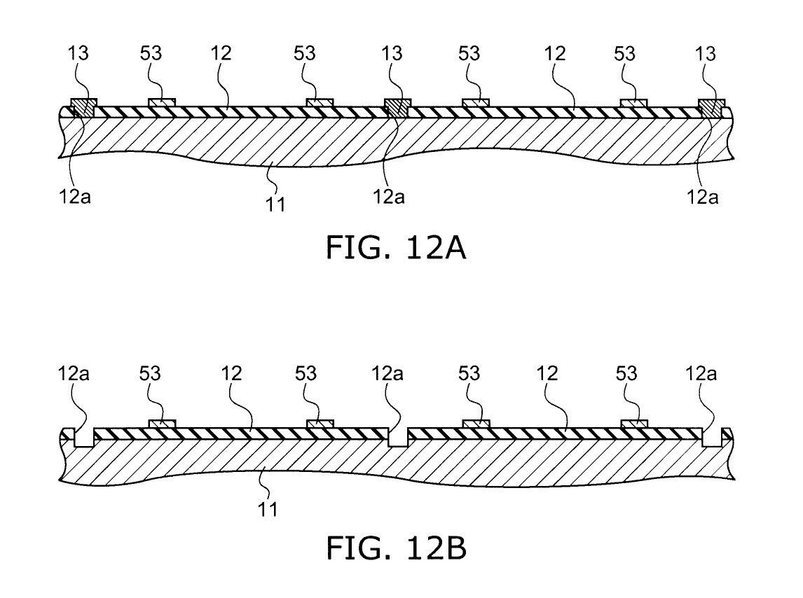

FIGS. 12A and 12B are process cross-sectional views illustrating a method for manufacturing a semiconductor device according to variations of this embodiment.

As shown in FIG. 12A, in the step shown in FIG. 6F in the above third embodiment, the silicon member 13 may be projected from the opening 12a. Alternatively, as shown in FIG. 12B, instead of providing a silicon member 13, it is also possible to dig down the silicon substrate 11 immediately below the opening 12a.

Next, a fourth embodiment of the invention is described.

This embodiment is also a method for manufacturing the semiconductor device according to the above first embodiment.

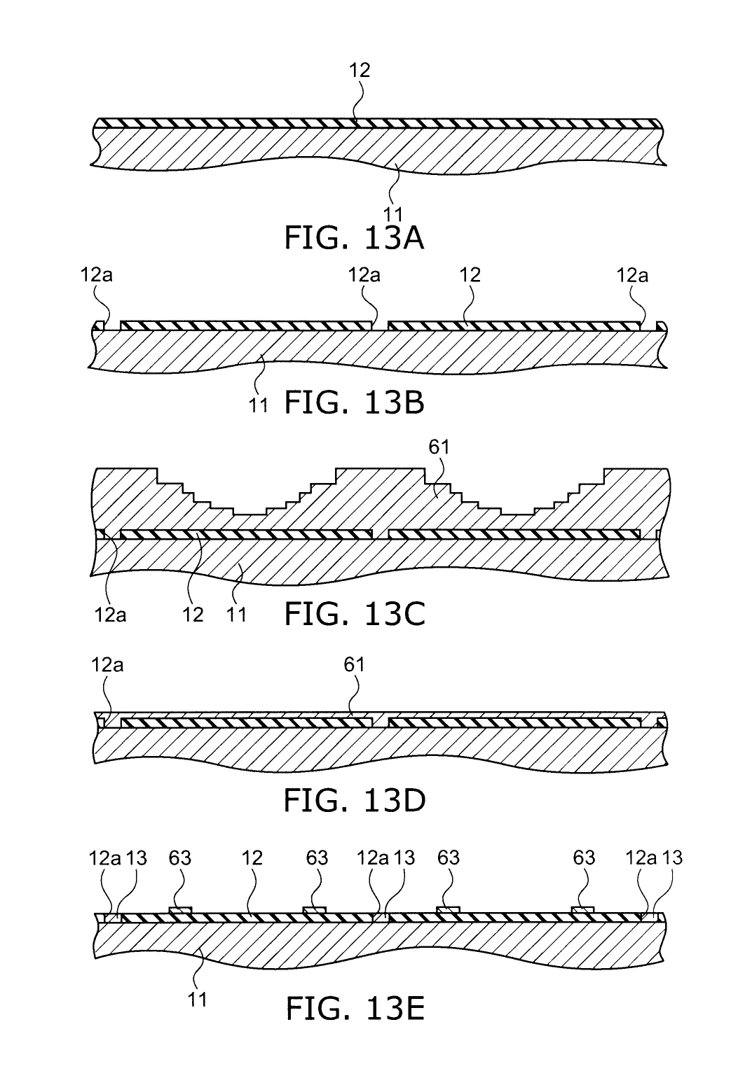

FIGS. 13A to 13E are process cross-sectional views illustrating a method for manufacturing a semiconductor device according to this embodiment.

As shown in FIG. 13A, like the above third embodiment, a dielectric film 12 is formed on a silicon substrate 11 made of single crystal silicon.

As shown in FIG. 13B, openings 12a are formed in the dielectric film 12. The silicon substrate 11 is exposed in the opening 12a.

As shown in FIG. 13C, selective epitaxial growth of silicon is performed on the dielectric film 12 to form an epitaxial silicon film 61. Here, the epitaxial silicon film 61 is in contact with the silicon substrate 11 through the opening 12a and grown starting at the silicon substrate 11. More specifically, the epitaxial silicon film 61 is formed by selective epitaxial growth of silicon starting at the portion of the silicon substrate 11 exposed to the opening 12a. Hence, the epitaxial silicon film 61 is formed thick in the region immediately above the opening 12a and thin in the region therearound.

As shown in FIG. 13D, an upper surface of the epitaxial silicon film 61 is flattened by CMP. Thus, the epitaxial silicon film 61 is reduced in thickness and planarized. As shown in FIG. 13E, the planarized epitaxial silicon film 61 is patterned to form a seed layer 63. The position for forming the seed layer 63 is the same as the position for forming the seed layer 53 in the above third embodiment.

The subsequent steps are the same as those shown in FIGS. 7 to 10 in the above third embodiment. Also in this embodiment, the semiconductor device 1 (see FIGS. 1 and 2) according to the above first embodiment can be manufactured. The manufacturing method other than the foregoing, and the operation and effect of this embodiment are the same as those of the above third embodiment. In addition, this embodiment also allows such variations as shown in FIGS. 12A and 12B.

Next, a fifth embodiment of the invention is described.

This embodiment is a method for manufacturing the semiconductor device according to the above variation of the first embodiment.

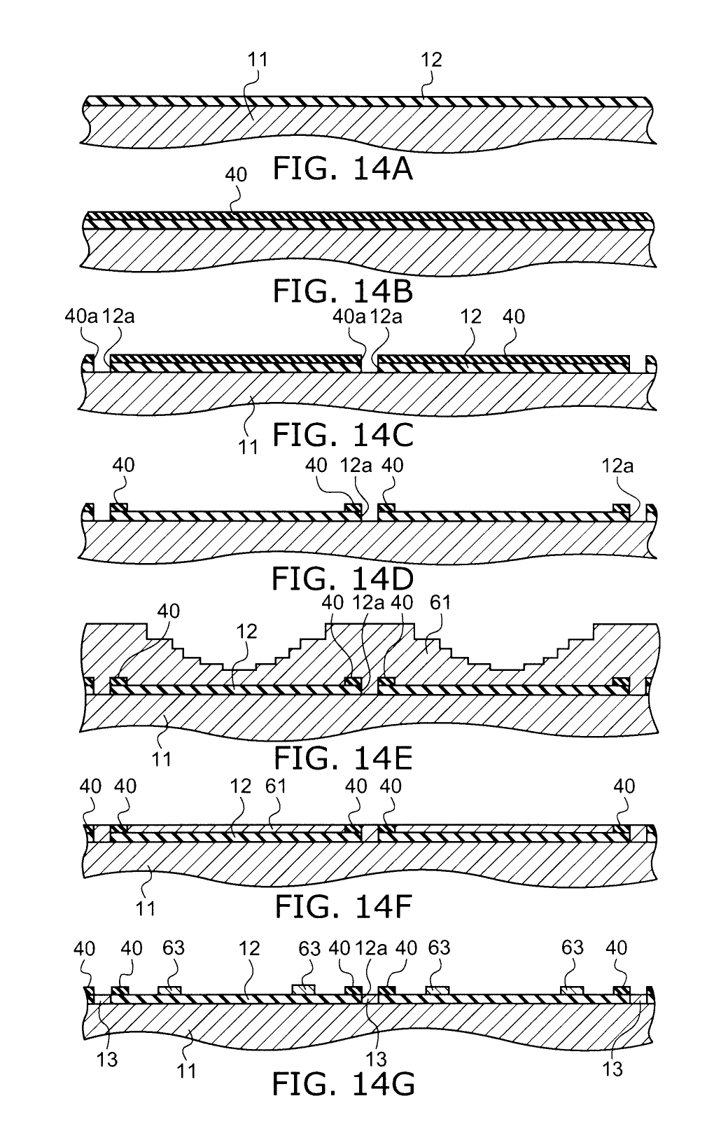

FIGS. 14A to 14G are process cross-sectional views illustrating a method for manufacturing a semiconductor device according to this embodiment.

As shown in FIG. 14A, like the above third embodiment, a dielectric film 12 is formed entirely on a silicon substrate 11 made of single crystal silicon. The dielectric film 12 is illustratively formed from alumina.

As shown in FIG. 14B, a dielectric film 40 is formed entirely on the dielectric film 12. The dielectric film 40 is illustratively formed from silicon nitride.

As shown in FIG. 14C, openings 12a are formed in the dielectric film 40 and the dielectric film 12 by RIE or other etching on the dielectric film 40 and the dielectric film 12. Here, the opening 12a is formed immediately below the opening 40a. The silicon substrate 11 is exposed in the opening 12a.

As shown in FIG. 14D, the dielectric film 40 is patterned and locally left. For instance, the dielectric film 40 is left at the edge of the opening 12a.

As shown in FIG. 14E, selective epitaxial growth of silicon is performed on the dielectric film 12 to form an epitaxial silicon film 61. Here, the epitaxial silicon film 61 is grown starting at the silicon substrate 11 exposed in the opening 12a, and hence is formed thick in the region immediately above the opening 12a and thin in the region therearound. The dielectric film 40 is buried in the epitaxial silicon film 61.

As shown in FIG. 14F, an upper surface of the epitaxial silicon film 61 is flattened by CMP. Thus, the epitaxial silicon film 61 is reduced in thickness and planarized. Here, CMP is stopped when the dielectric film 40 is exposed. That is, the dielectric film 40 is used as a CMP stopper film.

As shown in FIG. 14G, the planarized epitaxial silicon film 61 is patterned to form a seed layer 63. The position for forming the seed layer 63 is the same as the position for forming the seed layer 53 in the above third embodiment, that is, the position where the dielectric film 40 is not placed.

The subsequent steps are the same as those shown in FIGS. 7 to 10 in the above third embodiment. Thus, the semiconductor device is (see FIG. 3) according to the above variation of the first embodiment can be manufactured.

According to this embodiment, a dielectric film 40 is formed in the step shown in FIG. 14B, and the dielectric film 40 is patterned in the step shown in FIG. 14C. Thus, the dielectric film 40 can be used as a CMP stopper film in the step shown in FIG. 14F. That is, it is possible to determine the endpoint of CMP easily. The manufacturing method other than the foregoing, and the operation and effect of this embodiment are the same as those of the above third embodiment. In addition, this embodiment also allows such variations as shown in FIGS. 12A and 12B.

Next, a sixth embodiment of the invention is described.

This embodiment is a method for manufacturing the semiconductor device according to the above second embodiment.

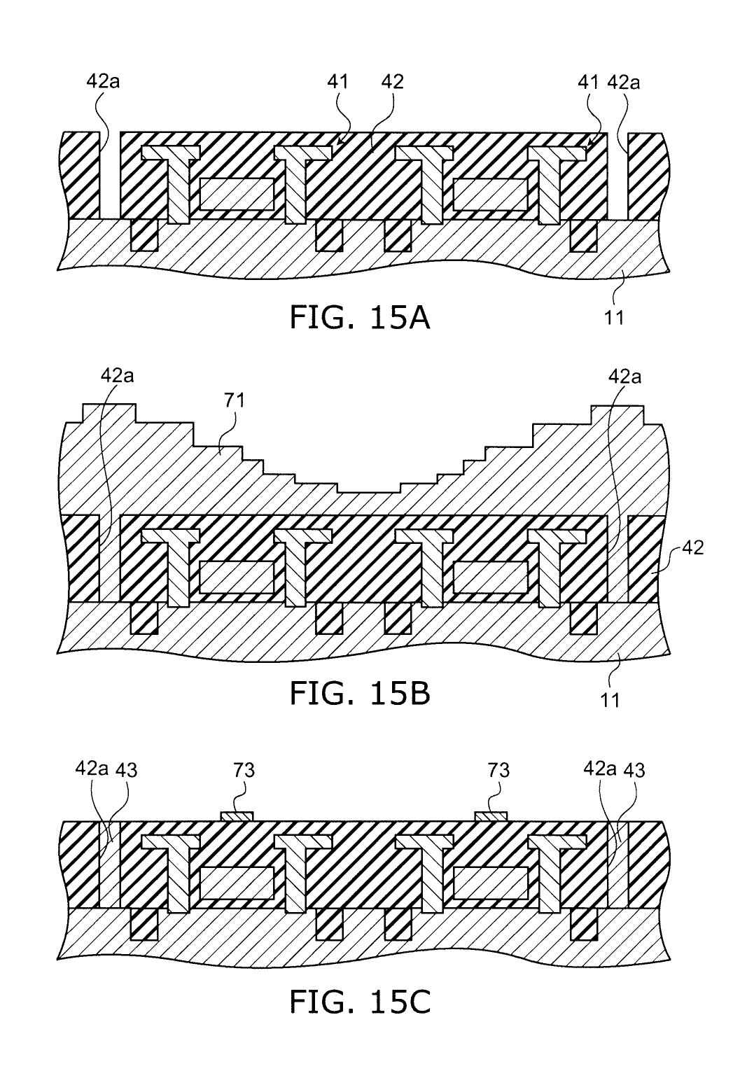

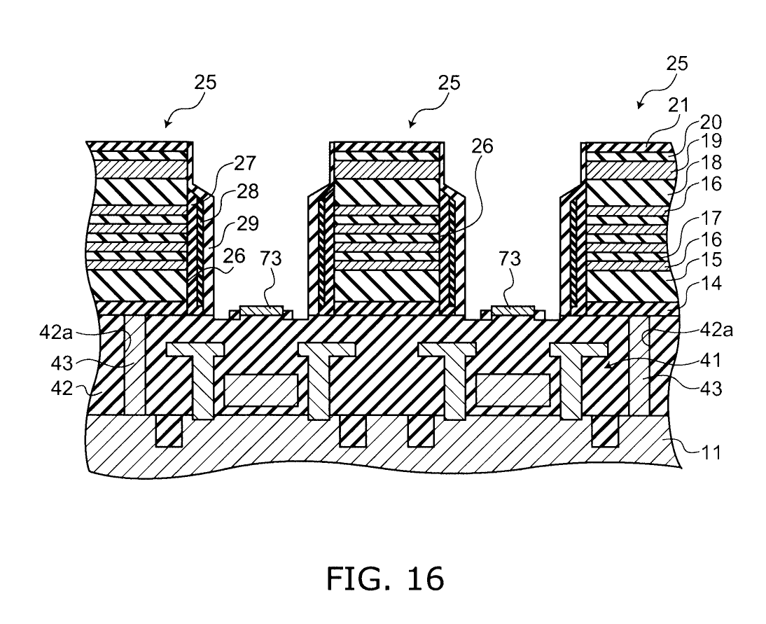

FIGS. 15A to 15C and 16 are process cross-sectional views illustrating a method for manufacturing a semiconductor device according to this embodiment.

As shown in FIG. 15A, a silicon substrate 11 made of single crystal silicon is prepared. Then, peripheral elements 41 are formed by conventional methods in and above the silicon substrate 11. The peripheral elements 41 illustratively include high-voltage transistors. Then, an interlayer dielectric film 42 is formed on the silicon substrate 11 so as to bury the peripheral elements 41. Next, through trenches 42a extending in one direction and reaching the silicon substrate 11 are formed in regions of the interlayer dielectric film 42 where the peripheral elements 41 are not placed. The through trenches 42a are openings of the interlayer dielectric film 42, and the silicon substrate 11 is exposed at the bottom thereof.

As shown in FIG. 15B, selective epitaxial growth of silicon is performed on the interlayer dielectric film 42 to form an epitaxial silicon film 71. Here, the epitaxial silicon film 71 is buried also in the through trench 42a, brought into contact with the silicon substrate 11 at the bottom of the through trench 42a, and grown starting at the silicon substrate 11. Hence, the epitaxial silicon film 71 is formed thick in the region immediately above the through trench 42a and thin in the region therearound.

As shown in FIG. 15C, the thickness of the epitaxial silicon film 71 is reduced and the epitaxial silicon film 71 is planarized by CMP. Then, the epitaxial silicon film 71 is patterned to form a seed layer 73. The seed layer 73 is formed in a region deviated from immediately above the through trench 42a and also deviated from immediately above the midpoint of the adjacent through trenches 42a. Furthermore, the seed layer 73 is formed in a striped configuration extending in the same direction as the through trench 42a. For instance, the seed layer 73 is formed immediately above the midpoint between the through trench 42a and the midpoint between the adjacent through trenches 42a. On the other hand, the epitaxial silicon film 71 remains also inside the through trench 42a and constitutes a silicon member 43.

The same steps as those shown in FIGS. 7A to 9A in the above third embodiment are performed. Thus, as shown in FIG. 16, a multilayer body 25 is formed on the interlayer dielectric film 42, and trenches 26 are formed in the multilayer body 25. A block film 27, a charge film 28, and a tunnel film 29 are laminated on the side surface of the trench 26. The seed layer 73 is exposed at the bottom surface of the trench 26.

Next, the same steps as those shown in FIGS. 9B to 10B are performed. Thus, a silicon pillar 33 is formed in the trench 26, and source lines 34, bit lines 37 and the like are formed on the multilayer body 25. Here, the silicon pillar 33 is formed by epitaxial growth starting at the seed layer 73. Hence, the silicon pillar 33 is formed from single crystal silicon and has the same crystal orientation as the silicon substrate 11. Thus, as shown in FIGS. 4 and 5, the semiconductor device 2 according to the above second embodiment is manufactured.

According to this embodiment, the silicon pillar 33 is formed by epitaxial growth indirectly from the silicon substrate 11 through the seed layer 73. Hence, the silicon pillar 33 can be formed from single crystal silicon while being insulated from the silicon substrate 11 by the interlayer dielectric film 42. Furthermore, the seed layer 73 is formed in a region deviated from the midpoint between the adjacent through trenches 42a. This can reliably prevent the seed layer 73 from including a boundary surface containing crystal defects.

The manufacturing method other than the foregoing, and the operation and effect of this embodiment are the same as those of the above third embodiment. In addition, this embodiment also allows such variations as shown in FIGS. 12A and 12B.

The invention has been described with reference to the embodiments. However, the invention is not limited to these embodiments. For instance, the above embodiments can be practiced in combination with each other. Furthermore, those skilled in the art can suitably modify the above embodiments by addition, deletion, or design change of components, or by addition, omission, or condition change of process steps, and such modifications are also encompassed within the scope of the invention as long as they fall within the spirit of the invention.

1. A semiconductor device comprising:
a semiconductor substrate made of a single crystal semiconductor material;
a dielectric film provided on the semiconductor substrate and including an opening; and
a semiconductor member provided on the dielectric film, placed in a region deviated from immediately above the opening, made of the single crystal semiconductor material, and separated from the semiconductor substrate.

2. The device according to claim 1, wherein
the opening is formed in a plurality of regions, and
the semiconductor member is placed in a region deviated from a midpoint between two adjacent ones of the openings.

3. The device according to claim 1, wherein the semiconductor member has the same crystal orientation as the semiconductor substrate.

4. The device according to claim 1, wherein the semiconductor member constitutes an active area of a plurality of memory cells arranged in a direction perpendicular to an upper surface of the semiconductor substrate.

5. The device according to claim 1, further comprising:
another dielectric film provided on a region of the dielectric film, the region being deviated from both the region immediately above the opening and a region where the semiconductor member is placed.

6. The device according to claim 1, further comprising:
another semiconductor member provided in the opening and epitaxially grown on the semiconductor substrate.

7. The device according to claim 1, further comprising:
an element formed inside the semiconductor substrate and the dielectric film.

8. A semiconductor device comprising:
a semiconductor substrate made of a single crystal semiconductor material;
a dielectric film provided on the semiconductor substrate and including an opening extending in one direction;
a multilayer body provided on the dielectric film, including a plurality of electrode films and a plurality of interlayer dielectric films alternately stacked, and including a trench extending in the one direction in a region deviated from immediately above the opening;
a charge film provided on a side surface of the trench;
a U-shaped semiconductor pillar provided on the side surface and a bottom surface of the trench, made of the single crystal semiconductor material, separated from the semiconductor substrate, and extending along the side surface and the bottom surface of the trench;
a source line provided on the multilayer body and connected to one end of the semiconductor pillar; and
a bit line provided on the multilayer body and connected to the other end of the semiconductor pillar.

9. The device according to claim 8, wherein
the opening is formed in a plurality of regions, and
the semiconductor pillar is placed in a region deviated from a midpoint between two adjacent ones of the openings.

10. The device according to claim 8, further comprising:
a semiconductor member provided in the opening and epitaxially grown on the semiconductor substrate.

11. The device according to claim 8, further comprising:
another dielectric film provided on a region of the dielectric film, the region being deviated from both the region immediately above the opening and the region where the semiconductor member is placed.

12. The device according to claim 11, wherein the semiconductor material is silicon, the dielectric film is made of alumina, and the other dielectric film is made of silicon nitride.

13. The device according to claim 8, further comprising:
an element formed inside the semiconductor substrate and the dielectric film.

14. A method for manufacturing a semiconductor device, comprising:
forming a dielectric film on a semiconductor substrate made of a single crystal semiconductor material;
forming an opening in the dielectric film;
forming a first semiconductor film on the dielectric film, the first semiconductor film being in contact with the semiconductor substrate through the opening and crystallized starting at the semiconductor substrate;
forming a seed layer made of the single crystal semiconductor material in part of a region deviated from immediately above the opening by selectively removing the first semiconductor film;
forming a second semiconductor film covering the seed layer and crystallized starting at the seed layer; and
forming a semiconductor member separated from the semiconductor substrate and made of the single crystal semiconductor material by selectively removing the second semiconductor film.

15. The method according to claim 14, wherein
the opening is formed in a plurality of regions, and
the seed layer is formed in a region deviated from a midpoint between two adjacent ones of the openings.

16. The method according to claim 14, wherein
the forming the first semiconductor film includes:
depositing an amorphous semiconductor film on the dielectric film and bringing the amorphous semiconductor film into contact with the semiconductor substrate in the opening; and
causing solid-phase epitaxial growth of the amorphous semiconductor film starting at its portion in contact with the semiconductor substrate through the opening.

17. The method according to claim 14, wherein
the forming the first semiconductor film includes:
forming an epitaxial semiconductor film on the dielectric film by selective epitaxial growth of the semiconductor material starting at a portion of the semiconductor substrate exposed to the opening; and
planarizing the epitaxial semiconductor film.

18. The method according to claim 14, further comprising:
forming another dielectric film on the dielectric film; and
selectively removing and locally leaving the other dielectric film,
the forming the seed layer including:
planarizing the first semiconductor film using the locally left other dielectric film as a stopper; and
selectively removing the first semiconductor film.

19. The method according to claim 14, further comprising:
forming an element in and above the semiconductor substrate,
the dielectric film being formed so as to bury the element.

20. The method according to claim 14, wherein the opening is formed so as to extend in one direction, the method further comprising:
forming a multilayer body on the dielectric film by alternately stacking a plurality of electrode films and a plurality of interlayer dielectric films so as to cover the seed layer;
forming a trench extending in the one direction in the multilayer body to expose the seed layer at the bottom of the trench;
forming a charge film on a side surface of the trench;
forming an amorphous semiconductor film in contact with the seed layer inside the trench;
forming an epitaxial semiconductor film by solid-phase epitaxial growth of the amorphous semiconductor film starting at the seed layer;
forming a U-shaped semiconductor pillar by dividing the epitaxial semiconductor film along the extending direction of the trench;
forming a source line on the multilayer body and connecting the source line to one end of the semiconductor pillar; and
forming a bit line on the multilayer body and connecting the bit line to the other end of the semiconductor pillar.
